(19) United States
(12) Patent Application Publication
(10) Pub. No.: US 2006/0272838 A1
(43) Pub. Date: Dec. 7, 2006

(54) Protection device for electronic components

(76) Inventor: Hans-Joachim Sauerzweig, Eickendorf (DE)

Correspondence Address: LERNER GREENBERG STEMER LLP, P O BOX 2480, HOLLYWOOD, FL, 33022-2480, US

(21) Appl. No.: 10/570,093

(22) PCT Filed: Jul. 30, 2004
(86) PCT No.: PCT/DE04/01758

§ 371 Date: Mar. 1, 2006

(30) Foreign Application Priority Data
Sep. 1, 2003 (DE) 10340895.9

(51) Int. Cl. H05K 5/00

(52) U.S. Cl. 174/17 SF

(57) ABSTRACT

The invention relates to a protection device for electronic components, especially memory modules. The electronic component(s) is/are incorporated into a first mineral-based protective covering with frost-protected water in a silicon potted manner. A first protective covering containing a ceramic pouring compound, can be provided.

The invention relates to a protective apparatus for electronic components, in particular memory modules.

Electronic components frequently have to be protected against short-term as well as long-lasting temperature influences, which can occur both during operation and during storage, and against the influences of severe mechanical loads, as well. In this case, particularly when carrying out research into the causes of accidents in traffic, it is of major importance to obtain the contents of electronic memories following extreme loads such as those after a fire, an explosion or a vehicle crash. These objects are achieved by flight data recorders, which are generally known by the expression “black box” from aviation. However, flight data recorders are much too expensive in comparison to the costs of land vehicles. The high prices result essentially from the high-quality materials and complex manufacturing processes.

As far as possible temperature protection is intended to be ensured without any external forced cooling. Protective requirements are stipulated by Norms and Standards. The temperature resistance requirements in accordance with IEEE Standard 1482.1-1999 Section 4.5, subparagraph “Fire”, for example, are as follows: 650° C. for 0.5 hours, 300° C. for 1 hour and 100° C. for 5 hours. The effect of known insulation materials is based on their poor thermal conductivity. In order to achieve the temperature resistance stipulated above with these materials, the thermal insulation must be many times larger than the volume of the electronics to be protected. Complex design measures are required in order to reduce the insulation volume, in particular by the arrangement of additional heat reflection layers and by the use of the Dewar principle, which is known from vacuum flasks. A further disadvantage of the known insulation materials with very poor thermal conductivity is that the heat dissipation which is required as a result of the power consumption of the electronics is considerably more difficult.

An apparatus for measured-value recording in the high-temperature range is known from DE 299 04 858 U1, in which the electronic circuit is surrounded by ceramic which can absorb water. A maximum operating temperature of 125° C. can be tolerated at times by the use of the energy which is required for vaporization of the water for cooling of the circuit.

The invention is based on the object of specifying a protective apparatus for electronic components, which guarantees adequate protection, based on IEEE 1482 as cited above, with respect to high temperatures and severe external mechanical influences, as well as a high degree of protection against damaging liquids, and which allows improved heat dissipation from the electronic components to the exterior.

The object is achieved by the characterizing features of claim 1. The process of embedding silicone-encapsulated electronic components in a protective sleeve on a mineral base, which has a material component with a high thermal storage capacity, specifically water, results in very effective temperature protection, with the heat dissipation from the electronic components at the same time being made easier in comparison to the known insulation materials with very poor thermal conductivity. The electronic components are preferably embedded in a 2-component silicone with a stainless-steel sheath. The silicone carries out the tasks of electrical insulation, protection against mechanical vibration and oscillations, and the fixing of the electronics.

Even without a stainless-steel sheath, this system is normally embedded in the material which has a high thermal capacity by virtue of a phase change, and keeps damaging external heat away from the electronics, by heat absorption. These materials are often waxes, parafines, esters or bicarbonates, with the known disadvantages of the difficulties in processing them, the high costs and the considerably environmental pollution.

According to the invention, the embedding material is a mineral system with a high proportion of air, in which water is bonded, with an antifreeze agent, for example salt, ensuring that the body is not damaged even at temperatures below zero. As is generally known, water has the best thermal capacity. In comparison to frequently used ceramic insulation media, insulators based on minerals are distinguished by lower costs, lower weight and better environmental compatibility.

Taking account of additional mechanical resistance capability, the necessary heat dissipation from the interior and a defined temperature/time response which results from the specific operating conditions, the protective sleeve as claimed in claim 2 is preferably surrounded by a stainless-steel housing which has at least one thermostatic valve. In this case, the thermostatic valve acts as a thermal weak point. In the extreme, especially in the event of severe, long-lasting heat influences from the exterior, the water first of all absorbs the heat supplied from the exterior, is heated up to the boiling temperature, changes to the steam phase with further heat being absorbed, and enters the surrounding medium through the thermal weak point. During this process, the temperature in the electronics does not rise above the boiling temperature of water, that is to say not above about 100° C. The protective sleeve does not carry out its original function of constraining the heat flow until the entire water supply has been “consumed”.

The stainless-steel housing with the protective sleeve and the silicone-encapsulated electronic component can, as is claimed in claim 3, be embedded in a further protective sleeve composed of or with a ceramic encapsulation compound. In addition to providing mechanical protection, this encapsulation compound also carries out the task of thermal protection comprising having to be a poor thermal conductor itself, of releasing bonded water on being heated, and of dissipating the steam slowly to the exterior from the thermostatic valve. The water that is released in this case assists the heat absorption.

A further stainless-steel housing is provided, as claimed in claim 4, as an external closure, and is used for mechanical protection of the internal components and for fixing the entire system. The stainless-steel sheath on the silicone-encapsulated electronics component and the two stainless-steel housings for the mineral-based insulation material and for the ceramic encapsulation compound not only carry out the function of a mount for the protective sleeves. In conjunction with the protective sleeves, they are also designed in such a way that foreign bodies entering from the exterior are constrained, while the electronic components are kept free of static pressures that occur, extremely severe accelerations, externally acting damaging liquids and chemicals such as water, oils, fuels, fire-protective agents, etc., based on IEEE 1482.1, as cited above.

A protective apparatus such as this occupies only a fraction of the volume of a standard temperature protective structure and, furthermore, can be produced at low cost.

The invention will be explained in more detail in the following text with reference to exemplary embodiments that are illustrated in the figures, in which:

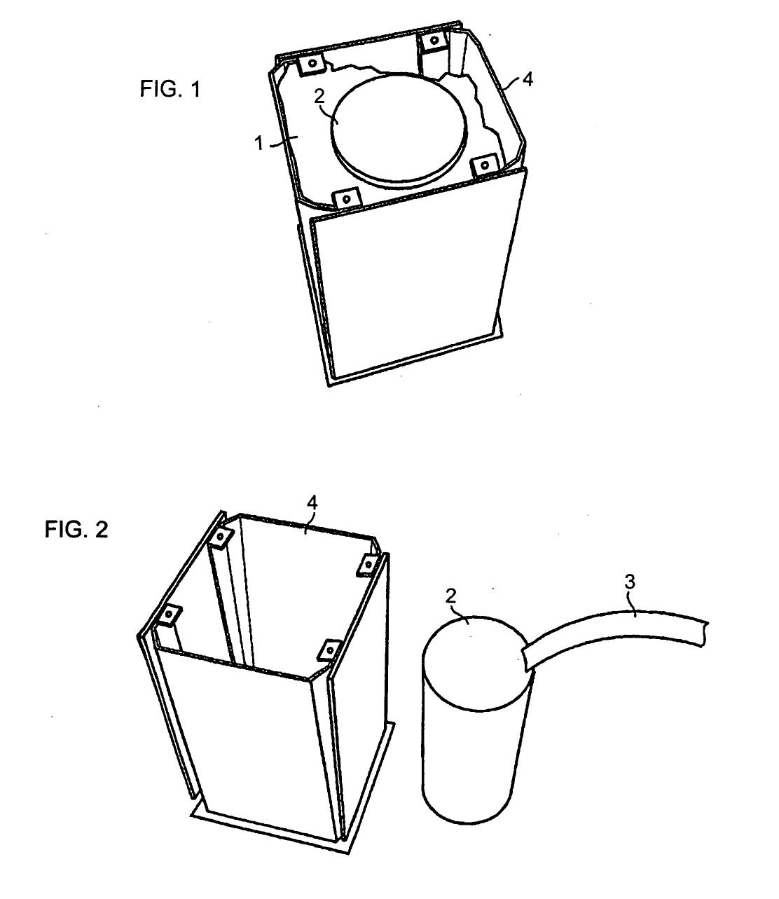

FIG. 1 shows a thermal protective apparatus after a test,

FIG. 2 shows components of a thermal protective apparatus,

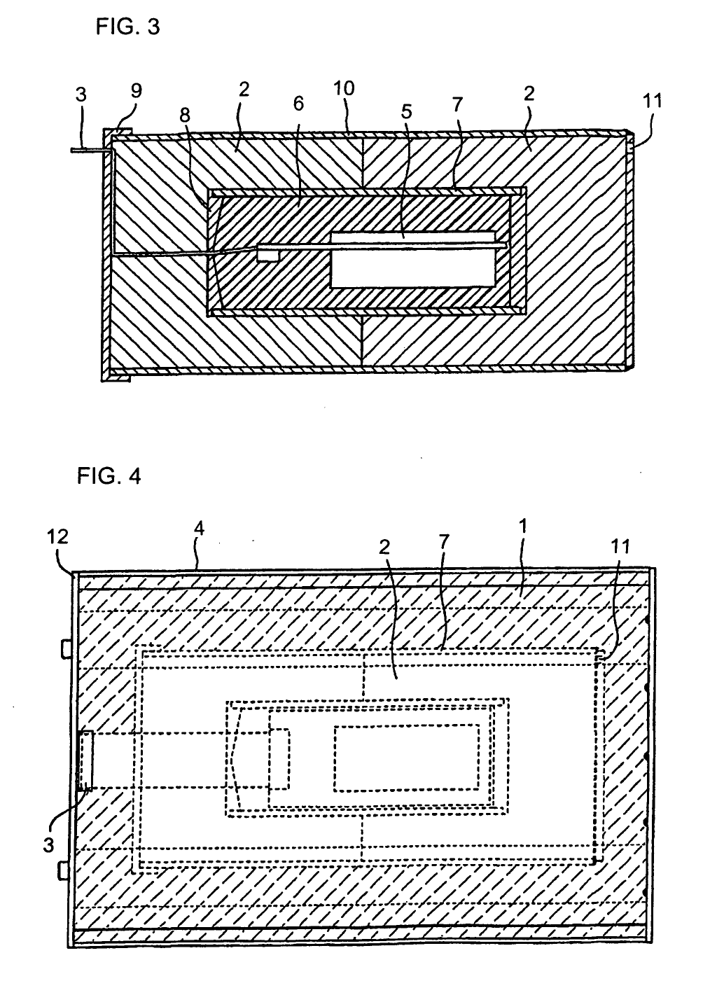

FIG. 3 shows a cross section through a protective apparatus having a protective sleeve, and

FIG. 4 shows a cross section through a protective apparatus having two protective sleeves.

FIGS. 1 and 2 show the major components of a thermal protective apparatus with a second protective sleeve 1 in the form of a pot, and a first protective sleeve 2 in the form of a block, in which an electronic component, for example an electronic memory module 5 (FIGS. 3 and 4) is encapsulated, although only the connecting line 3 which is passed to the exterior from the electronic memory module can be seen in FIG. 2. The first protective sleeve 2 in the form of a block is inserted into the interior of the second protective sleeve 1, which is in the form of a pot. In this case, the second protective sleeve 1 may be held, for example, by means of a stainless-steel housing 4. The first protective sleeve 2 in the form of a block is composed of a material with a high thermal storage capacity, while the second protective sleeve 1, which is in the form of a pot, is composed of a material with poor thermal conductivity. This material mix ensures that, on the one hand, the thermal protective apparatus has good temperature resistance, and on the other hand that the dissipation of the heat resulting from the power losses in the memory module 5 is not made unnecessarily difficult. The block form of the first protective sleeve 2 can be adapted such that it accurately fits the pot shape of the second protective sleeve 1. However, versions with intermediate spaces are also feasible, which are partially or entirely filled with a vacuum, a further insulation material filling, or heat reflection layers.

FIG. 3 shows a cross section through a protective apparatus with only one protective sleeve. The electronic memory module 5 is embedded in a silicone encapsulation compound 6, which is surrounded by a stainless-steel sheath 7 with a cover 8. The connecting line 3 of the electronic memory module 5 projects through the silicone encapsulation compound 6, the cover 8, the first protective layer 2 and the cover 9 on a first stainless-steel housing 10. The first protective sleeve 2 is in this case composed of a thermal insulation medium on a mineral base, with the mineral base material containing an air component and bonded water, which has an antifreeze agent in order to prevent icing. The first stainless-steel housing 10 is equipped with a thermostatic valve 11, which allows water vapor or steam to be dissipated to the surrounding area in the event of an excessively high thermal load.

FIG. 4 shows this configuration rotated through 90° and with an additional, second protective sleeve 1. In this case, the second protective sleeve 1 is essentially composed of a ceramic encapsulation compound, whose pores can be entered, when required by water vapor or steam via the thermostatic valve 11. The ceramic encapsulation compound as the second protective sleeve 1 is surrounded on all sides by the second stainless-steel housing 4, together with a cover 12.

The invention is not restricted to the exemplary embodiments specified above. In fact, a number of versions are feasible which also make use of the features of the invention in versions of fundamentally different types.

1-4. (canceled)

5. A protective device for one or more electronic components, comprising:
a first protective sleeve formed of a mineral basis with frost-protected water, and said sleeve enclosing the one or more electronic components encapsulated in silicone.

6. The protective device according to claim 5, wherein the one or more electronic components comprise memory modules.

7. The protective device according to claim 5, which further comprises a first stainless-steel housing surrounding said first protective sleeve, said first stainless-steel housing having at least one thermostatic valve.

8. The protective device according to claim 7, which further comprises a second protective sleeve enclosing said first stainless-steel housing with said first protective sleeve embedded in a ceramic encapsulation compound.

9. The protective device according to claim 8, which further comprises a second stainless-steel housing enclosing said second protective sleeve.
